(19) United States
(12) Patent Application Publication
(10) Pub. No.: US 2014/0091853 A1
(43) Pub. Date: Apr. 3, 2014

(54) SWITCHING CIRCUIT

(71) Applicant: Masayuki OKANO, Mizuho-shi (JP)

(72) Inventor: Masayuki OKANO, Mizuho-shi (JP)

(73) Assignees: KABUSHIKI KAISHA TOYOTA JIDOSHOKKI, Kariya-shi (JP); TOYOTA JIDOSHA KABUSHIKI KAISHA, Toyota-shi (JP)

(21) Appl. No.: 14/024,084

(22) Filed: Sep. 11, 2013

(30) Foreign Application Priority Data
Oct. 1, 2012 (JP) 2012-219436

(51) Int. Cl. H03K 17/08

(52) U.S. Cl. CPC H03K 17/08
USPC 327/427

(57) ABSTRACT

A switching circuit includes first and second switching elements arranged in parallel in an energization path, first and second gate driving lines, first and second fuses, and first and second abnormality detection portions capable of detecting abnormality in the switching elements. In the switching circuit, when abnormality in either one of the first and second switching elements is detected, the fuse between the first and second fuses which corresponds to the switching element in which abnormality is detected is turned into non-conduction state.

INCORPORATION BY REFERENCE

The disclosure of Japanese Patent Application No. 2012-219436 filed on Oct. 1, 2012 including the specification, drawings and abstract is incorporated herein by reference in its entirety.

### BACKGROUND OF THE INVENTION

1. Field of the Invention

The present invention relates to a switching circuit.

2. Description of Related Art

A motor driving device for driving a motor is installed in an electric vehicle or a hybrid electric vehicle. A motor driving device is configured with a switching circuit. The switching circuit includes a power semiconductor device. The power semiconductor device is switched between an ON state and an OFF state, thereby switching an energization path connecting a power source with a motor between a conduction state and a non-conduction state. In such a motor driving device, a failure in a power element leads to an impaired function of the motor driving device. Particularly, when the power element is damaged in the ON state, the motor cannot be controlled, and, in addition, current continuously flows through the motor. This may result in overheating or the like of the motor. Accordingly, it is desired that damage to the power element be prevented in the switching circuit of the motor driving device. Japanese Patent Application Publication No. 10-145205 (JP 10-145205 A) discloses a technology in which an actuation of the power element is disabled before the power element is damaged in order to prevent damage to the power element installed in the switching circuit. In the switching circuit disclosed in JP 10-145205 A, when a temperature increase of the power element is detected, a gate driving line for transmitting a gate signal to a gate of the power element is disconnected. This prevents the subsequent actuation of the power element and thus prevents the damage due to continuous use of the power element from being caused.

However, in the switching circuit disclosed in JP 10-145205 A, in a case where the power element in which an abnormal phenomenon has been detected is disabled, the function of the switching circuit is also disabled. As a result, the switching circuit becomes incapable of driving a load device (such as a motor).

### SUMMARY OF THE INVENTION

The present invention provides a switching circuit which can reduce stoppage of functions in a circuit in a case where an actuation of an element in which an abnormal phenomenon is detected is disabled.

A switching circuit for switching a state of an energization path between a conduction state and a non-conduction state according to one aspect of the invention, the switching circuit includes: a first switching element which is arranged in the energization path, turns into the non-conduction state in a case where a gate-on voltage is not applied to a gate, and turns into the conduction state in a case where the gate-on voltage is applied to the gate; a second switching element which is arranged in parallel with the first switching element in the energization path, turns into the non-conduction state in a case where a gate-on voltage is not applied to a gate, and turns into the conduction state in a case where the gate-on voltage is applied to the gate; a first abnormality detection portion having a capacity of detecting abnormality in the first switching element; a second abnormality detection portion having a capacity of detecting abnormality in the second switching element; a gate driving signal output section which applies the gate-on voltage to each of gate terminals of the first switching element and the second switching element; a first gate driving line which connects the gate driving signal output section with the gate terminal of the first switching element; a second gate driving line which connects the gate driving signal output section with the gate terminal of the second switching element; a first fuse which is provided in the first gate driving line and turns the first gate driving line into the non-conduction state in a case where the first abnormality detection portion detects abnormality in the first switching element; and a second fuse which is provided in the second gate driving line and turns the second gate driving line into the non-conduction state in a case where the second abnormality detection portion detects abnormality in the second switching element.

According to the above aspect, even when an actuation of the switching element is disabled clue to abnormality in the switching element, stoppage of functions of the switching circuit can be reduced.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a diagram showing a configuration of a switching circuit of the present invention;

FIG. 2 is a diagram showing a circuit configuration of a motor driving device of the present invention;

FIG. 3 is a diagram showing configurations of the motor driving device and peripheral components of the present invention; and

FIG. 4 is a graph representing the relationship between an accelerator operation amount S1 and an electric power amount P1.

### DETAILED DESCRIPTION OF EMBODIMENTS

A switching circuit of the present invention may include a first short-circuit terminal and a second short-circuit terminal to which a reference voltage different from a gate-on voltage is applied. The switching circuit may include a first short-circuit line which has one end connected with a first gate driving line in a position between a first fuse and a first switching element and has another end connected with a first short-circuit terminal and a second short-circuit line which has one end connected with a second gate driving line in a position between a second fuse and a second switching element and has another end connected with a second short-circuit terminal. The switching circuit may include a first switch which is provided in the first short-circuit line and turns the first short-circuit line into a conduction state when first abnormality detection portion detects abnormality in the first switching element and a second switch which is provided in the second short-circuit line and turns the second short-circuit line into the conduction state when second abnormality detection portion detects abnormality in the second switching element. In the switching circuit, when a gate driving signal output section applies the gate-on voltage to a gate of the first switching element in the conduction state of the first short-circuit line, current flows from the gate driving signal output section to the first short-circuit terminal, and the first fuse may turn into the non-conduction state. In the switching circuit, when a gate driving signal output section applies the gate-on voltage to the gate of the second switching element in the conduction state of the second short-circuit line, current flows from the gate driving signal output section to the second short-circuit terminal, and the second fuse may turn into the non-conduction state.

In the above switching circuit, the short-circuit lines connected with the gate driving lines are provided, and the fuses are thereby turned into non-conduction state by use of a signal (gate-on voltage) output from the gate driving signal output section. Accordingly, a simple circuit configuration enables turning the fuses provided in the gate driving lines into the non-conduction state.

In the switching circuit disclosed in the present invention, after abnormality in either one of the first switching element and the second switching element is detected, the gate driving signal output section may reduce electric power output from an energization path compared to electric power before detection of the abnormality.

In the above switching circuit, a load to the switching element whose actuation is not disabled is reduced, thus hindering abnormality from further occurring in the switching element.

In the switching circuit of the present invention, the first abnormality detection portion may be capable of detecting a temperature of the first switching element, and the second abnormality detection portion may be capable of detecting a temperature of the second switching element. In the switching circuit, the first fuse may turn into the non-conduction state when a determination is made that the first switching element is abnormal according to the temperature detected by the first abnormality detection portion, and the second fuse may turn into the, non-conduction state when a determination is made that the second switching element is abnormal according to the temperature detected by the second abnormality detection portion.

An above load driving device allows reduction of a failure of the switching element due to a temperature increase.

In the switching circuit of the present invention, the first abnormality detection portion may be capable of detecting current flowing through the first switching element, and the second abnormality detection portion may be capable of detecting current flowing through the second switching element. In the switching circuit, the first fuse may turn into the non-conduction state when a determination is made that the first switching element is abnormal according to the current detected by the first abnormality detection portion, and the second fuse may turn into the non-conduction state when a determination is made that the second switching element is abnormal according to the current detected by the second abnormality detection portion.

The above load driving device allows reduction of a failure of the switching element due to overcurrent.

In the switching circuit of the present invention, the first abnormality detection portion may be capable of detecting a voltage applied to the first switching element, and the second abnormality detection portion may be capable of detecting a voltage applied to the second switching element. In the switching circuit, the first fuse may turn into the non-conduction state when a determination is made that the first switching element is abnormal according to the voltage detected by the first abnormality detection portion, and the second fuse may turn into the non-conduction state when a determination is made that the second switching element is abnormal according to the voltage detected by the second abnormality detection portion.

The above load driving device allows reduction of a failure of the switching element due to an overvoltage.

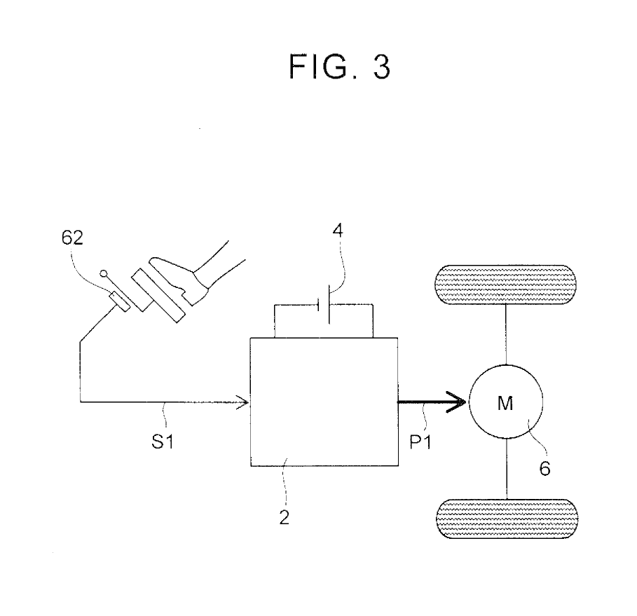

As shown in FIG. 3, a motor driving device 2 of this embodiment is connected with a direct current power source 4, a three-phase alternating current motor 6 (hereinafter referred to as “motor 6”), and an accelerator operation amount sensor 62. The accelerator operation amount sensor 62 outputs a motor driving signal in response to an opening of an accelerator. The motor driving signal is input to the motor driving device 2.

The motor driving device 2 is supplied with electric power from the direct current power source 4 and supplies output electric power to the motor 6 in response to the motor driving signal input from the accelerator sensor 62. More specifically, the motor driving device 2 supplies three-phase alternating current to an input terminal (not shown) of the motor 6.

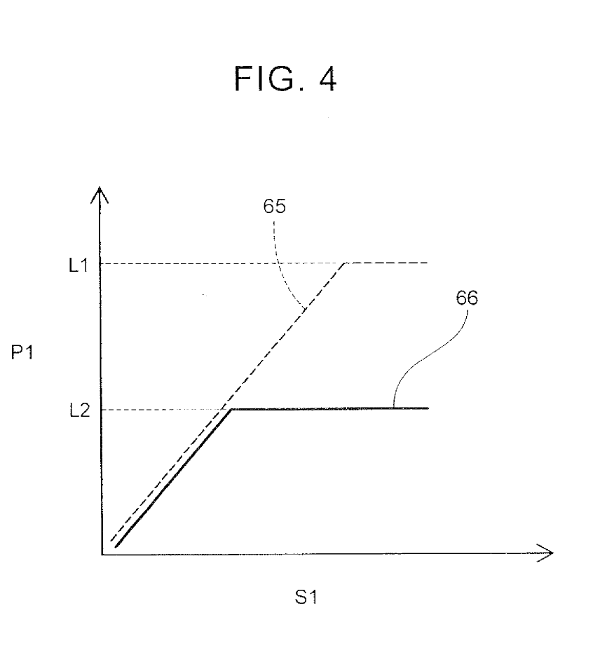

FIG. 4 represents the relationship between an accelerator operation amount S1 obtained from the motor driving signal and an electric power amount P1 supplied from the motor driving device. A broken line in FIG. 4 represents a standard mode characteristic 65. The standard mode characteristic 65 represents the relationship between the accelerator operation amount S1 and the electric power amount P1 in a normal state, that is, in a state where no abnormality in the switching element described later is detected. In the standard mode characteristic 65, the accelerator operation amount S1 and the magnitude of the electric power amount P1 are in a directly proportional relationship. However, when the level of the accelerator operation amount S1 exceeds a certain value, the magnitude of the electric power amount P1 becomes constant at an upper limit value L1. The motor driving device 2 controls the electric power amount P1 by PWM control. The motor driving device 2 adjusts a duty ratio so that the electric power amount P1 becomes a value corresponding to the level of the accelerator operation amount S1. Meanwhile, a solid line in FIG. 4 represents a protection mode characteristic 66. The protection mode characteristic 66 will later be described in detail.

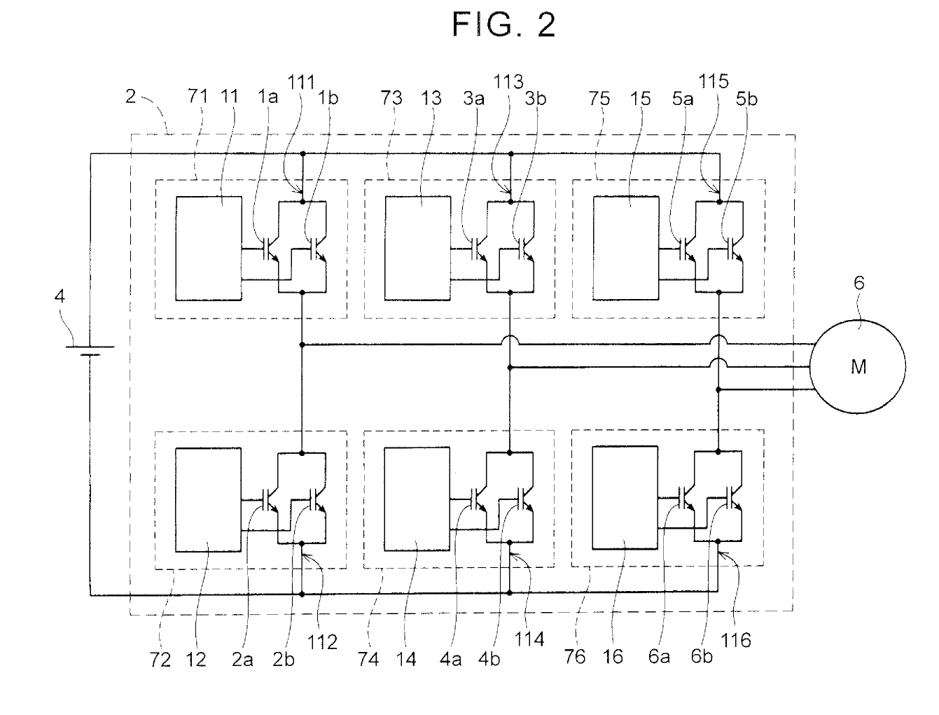

As shown in FIG. 2, the motor driving device 2 of this embodiment is configured with switching circuits 71 to 76. The switching circuit 71 includes a switching element driving circuit 11 and switching elements 1a, 1b. A so-called arm 111 is configured with the switching elements 1a, 1b. Similarly, the switching circuits 72 to 76 include respective switching element driving circuits 12 to 16 and switching elements 2a to 6a, 2b to 6b. Arms 112 to 116 are configured with the respective switching elements 2a to 6a, 2b to 6b. The arms 111 to 116 are connected with each other to form a three-phase inverter circuit. In other words, upper ends of the upper arms 111, 113, 115 are connected with a positive electrode of the direct current power source 4. Lower ends of the lower arms 112, 114, 116 are connected with a negative electrode of the direct current power source 4. A connecting portion between a lower end of the upper arm 111 and an upper end of the lower arm 112, a connecting portion between a lower end of the upper arm 113 and an upper end of the lower arm 114, and a connecting portion between a lower end of the upper arm 115 and an upper end of the lower arm 116 are each connected with the input terminal of the motor 6. The circuit configurations of the switching circuits 72 to 76 are the same as that of the switching circuit 71. Therefore, the switching circuit 71 will only be described in the following description.

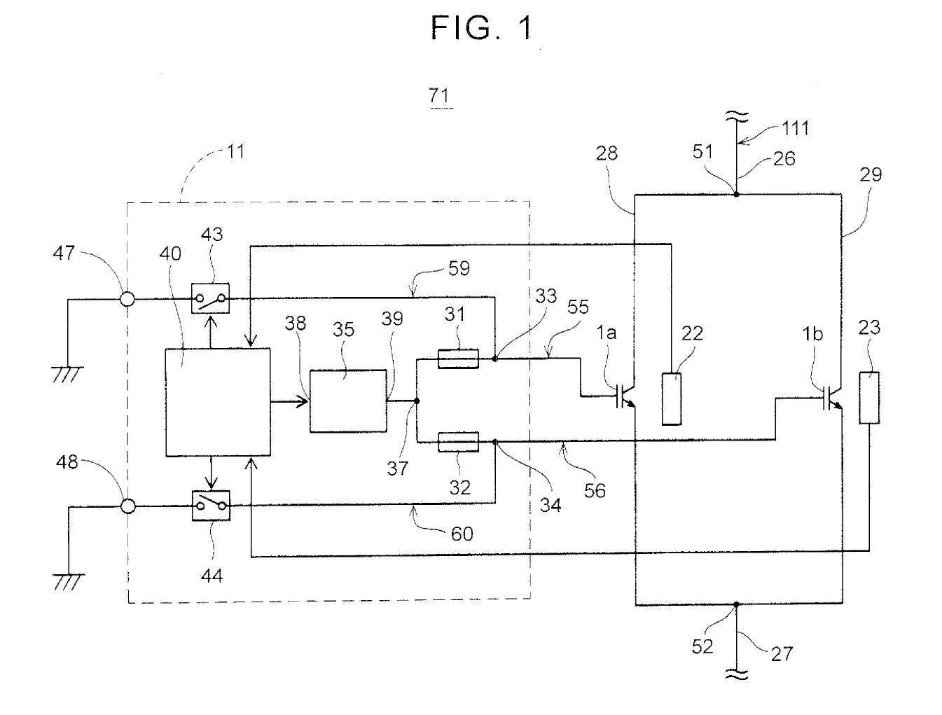

As shown in FIG. 1, in the switching circuit 71, a portion between a branch point 51 and a branch point 52 is split into a path 28 and a path 29, forming a parallel circuit. The switching element 1a is arranged in the path 28. The switching element 1b is arranged in the path 29. In other words, the switching element 1a and the switching element 1b are arranged in parallel in a path of the arm 111.

The switching elements 1a, 1b are IGBTs. In each of the switching elements 1a, 1b, current flows between a collector and an emitter when a gate-on voltage is applied to a gate. On the other hand, no current flows between the collector and the emitter of the switching element 1a or 1b when no gate-on voltage is applied to the gate.

As shown in FIG. 1, the switching element driving circuit 11 includes a control device 40, a gate driving circuit 35, gate driving lines 55, 56, fuses 31, 32, temperature sensors 22, 23, short-circuit lines 59, 60, and short-circuit switches 43, 44.

The control device 40 controls operations of the switching elements 1a, 1b. In other words, the above-described motor driving signal is input to the control device 40. The control devices of the switching circuits 71 to 76 output a control signal to the respective gate driving circuits in response to the input motor driving signal and control turning on or off of the respective switching elements 1a, 1b to 6a, 6b. Accordingly, direct current electric power supplied from the direct current power source 4 is converted into alternating current electric power, and the alternating current electric power resulting from the conversion is supplied to the motor 6. Further, signals from the temperature sensors 22, 23 are input to the control device 40. The control device 40, in response to the signals, outputs a control signal to the gate driving circuit 35 and performs control for turning on the short-circuit switches 43, 44. This control will later be described in detail.

The gate driving circuit 35 outputs a gate driving signal to the switching elements 1a, 1b in response to input of the control signal from the control device 40. In other words, the control signal from the control device 40 is input to an input terminal 38 of the gate driving circuit 35. The gate driving circuit 35 outputs a gate-on signal (voltage) to an output terminal 39 when the control signal from the control device 40 is input. Accordingly, the gate driving circuit 35 functions as a gate driving signal output section.

The gate driving lines 55, 56 connect the output terminal 39 of the gate driving circuit 35 with the switching elements 1a, 1b. In other words, a branch point 37 is connected with the output terminal 39 of the gate driving circuit 35, and one ends of the gate driving lines 55, 56 are connected with the branch point 37. The other end of the gate driving line 55 is connected with the gate of the switching element 1a. The other end of the gate driving line 56 is connected with the gate of the switching element 1b. Accordingly, when the gate-on signal (gate-on voltage) is output from the output terminal 39 of the gate driving circuit 35, the switching elements 1a and the switching elements 1b each turn into a conduction state (ON state). When a gate-off signal (gate-off voltage: specifically, a ground potential) is output from the output terminal 39 of the gate driving circuit 35, the switching elements 1a and the switching elements 1b each turn into a non-conduction state (OFF state).

The fuses 31, 32 function as conductors (lines) in a normal state. When current of a set magnitude or higher flows, the fuses 31, 32 are fused by Joule heat generated by the current, thereby turning into the non-conduction state. The fuse 31 is arranged in the gate driving line 55. When the fuse 31 is fused, the gate driving circuit 35 and the gate of the switching element 1a turn into the non-conduction state. The fuse 32 is arranged in the gate driving line 56. When the fuse 32 is fused, the gate driving circuit 35 and the gate of the switching element 1b turn into the non-conduction state.

The temperature sensors 22, 23 are sensors for detecting temperatures of the switching elements 1a, 1b. The temperature sensor 22 may be formed separately from the switching element 1a or may be formed on a same substrate. Similarly, the temperature sensor 23 may be formed separately from the switching element 1b or may be formed on a same substrate. The temperature sensors 22, 23 are connected with the control device 40. The temperatures of the switching elements 1a, 1b detected by the temperature sensors 22, 23 are input to the control device 40. The temperature sensors 22, 23 function as abnormality detection portion.

The short-circuit lines 59, 60 are lines to connect the gate driving lines 55, 56 to the ground potential. Specifically, one end of the short-circuit line 59 is connected with a branch point 33 of the gate driving line 55. The branch point 33 is provided in a position between the fuse 31 and the switching element 1a. The other end of the short-circuit line 59 is connected with a short circuit terminal 47. The short-circuit terminal 47 is connected to the ground potential. Similarly, one end of the short-circuit line 60 is connected with a branch point 34 of the gate driving line 56. The branch point 34 is provided in a position between the fuse 32 and the switching element 1b. The other end of the short-circuit line 60 is connected with a short circuit terminal 48 which is connected to the ground potential.

The short-circuit switches 43, 44 are switches whose ON state or OFF state is controlled by the control device 40. Specifically, the short-circuit switch 43 is arranged in the short-circuit line 59. The OFF state of the short-circuit switch 43 is a state where the one end of the short-circuit line 59 (that is, the branch point 33 of the gate driving line 55) is not electrically connected with the short-circuit terminal 47 (non-conduction state). When the short-circuit switch 43 is turned on, the one end of the short-circuit line 59 (that is, the branch point 33 of the gate driving line 55) is electrically connected with the short-circuit terminal 47, thereby grounding the branch point 33 of the gate driving line 55. Similarly, the OFF state of the short-circuit switch 44 is a state where the one end of the short-circuit line 60 (that is, the branch point 34 of the gate driving line 56) is not electrically connected with the short-circuit terminal 48 (non-conduction state). The short-circuit switch 44 is arranged in the short-circuit line 60. When the short-circuit switch 44 is turned on, the one end of the short-circuit line 60 (that is, the branch point 34 of the gate driving line 56) is electrically connected with the short-circuit terminal 48, thereby grounding the branch point 34 of the gate driving line 56.

As described below, the temperature sensors 22, 23 detect the temperatures of the switching elements 1a, 1b. When it is determined that abnormality is occurring in the switching element 1a or 1b according to the temperatures detected by the temperature sensors 22, 23, the control device 40 stops the subsequent operation of the switching element determined as abnormal. With reference to FIG. 1, an operation of the switching circuit 71 in a case where abnormality has been detected according to the temperature of the switching element 1a will be described below. Since the operation of the switching circuit 71 is the same in a case where abnormality occurs in the switching element 1b, a detailed description thereof will be omitted herein.

The temperature sensor 22 detects the temperature of the switching element 1a. The signal from the temperature sensor 22 (the signal corresponding to the temperature of the switching element 1a) is input to the control device 40. The control device 40 determines whether or not the temperature detected by the temperature sensor 22 (the temperature of the switching element 1a) is higher than a preset temperature. If the control device 40 determines that the temperature of the switching element 1a is higher than the preset temperature, the control device 40 turns on the short-circuit switch 43 which corresponds to the switching element 1a in which a temperature increase has been detected. Accordingly, the one end (branch point 33) of the short-circuit line 59 is electrically connected with the short-circuit terminal 47, thereby connecting the branch point 33 to the ground potential. As a result, the path which sequentially connects the output terminal 39 of the gate driving circuit 35, the fuse 31, the branch point 33, the short-circuit line 59, the short-circuit terminal 47, and the ground potential turns into the conduction state.

The control device 40 next outputs the control signal to the gate driving circuit 35. The gate driving circuit 35 then outputs the gate-on signal to the output terminal 39. As described above, because the path which sequentially connects the output terminal 39 of the gate driving circuit 35, the fuse 31, the branch point 33, the short-circuit line 59, the short-circuit terminal 47, and the ground potential is in the conduction state, when the gate-on signal is output to the output terminal 39, current flows from the output terminal 39, through the fuse 31, the short-circuit line 59, and the short-circuit terminal 47, to the ground potential. Here, the capacity of the fuse 31 is previously set such that the fuse 31 is fused by the current flowing between the output terminal 39 and the short-circuit terminal 47. Accordingly, when current flows through the fuse 31, the fuse 31 is fused, thereby turning the gate driving line 55 into the non-conduction state. On the other hand, because the one end (branch point 34) of the short-circuit line 60 and the short-circuit terminal 48 keep the non-conduction state, the gate driving line 56 is not disconnected. Therefore, after the gate driving line 55 is disconnected, when the gate-on signal is output from the output terminal 39, the gate-on voltage is not applied to the gate of the switching element 1a, but the gate-on voltage is only applied to the gate of the switching element 1b. In other words, after a temperature increase of the switching element 1a is detected, an actuation of the switching element 1a is disabled, and the switching element 1b only operates. This hinders a damage to the switching element 1a due to its subsequent actuation while the operation of the switching element 1b is sustained.

Further, in the switching circuit 71 of the motor driving device 2 of this embodiment, after the actuation of the switching element 1a in which abnormality has occurred is disabled, the conduction of the energization path can be controlled by the switching element 1b which is arranged in parallel with the switching element 1a. Accordingly, stoppage of the function of the switching circuit 71 for controlling the conduction of the energization path can be reduced, and the drive of the motor 6 can be sustained.

Next, an operation of the motor driving device 2 in a case where a temperature increase of the switching element 1a has been detected will be described. As described below, when a temperature increase of the switching element 1a has been detected, the motor driving device 2 reduces output electric power supplied to the motor 6 from the motor driving device 2 in the subsequent drive of the motor 6.

The solid line in FIG. 4 represents the protection mode characteristic 66. The protection mode characteristic 66 represents the relationship between the accelerator operation amount S1 and the electric power amount P1 in a state where abnormality in the switching element has been detected. In the protection mode characteristic 66, similarly to the standard mode characteristic 65, the accelerator operation amount S1 and the magnitude of the electric power amount P1 are in a directly proportional relationship. However, an upper limit value L2 of the protection mode characteristic 66 is low compared to the upper limit value L1 of the standard mode characteristic 65. Specifically, within the range where the upper limit value L2≦the upper limit value L1/2 is satisfied, the upper limit value L2 is appropriately determined.

Accordingly, in the motor driving device 2 of this embodiment, the magnitude of the electric power amount P1 with respect to the accelerator operation amount S1 is reduced after a temperature increase has been detected compared to before the temperature increase is detected. A load to the switching element 1b whose actuation is not disabled is thereby reduced, thus hindering abnormality from further occurring in the switching element 1b.

In the motor driving device 2 of the above-described embodiment, abnormality in the switching element is detected by the temperature of the switching element. However, a method for detecting abnormality in the switching element may employ detection of abnormality by current at the switching element. In this case, known current detection means (sense region) is formed in each of the switching elements 1a, 1b to 6a, 6b, current flowing through the switching elements 1a, 1b can be detected from sense current flowing through the sense region. In a case where the current flowing through the switching elements 1a, 1b exceeds a preset current value (in a case where so-called overcurrent flows), the fuses 31, 32 may turn into the non-conduction state, determining that abnormality has occurred in the switching elements 1a, 1b. Moreover, a method for detecting abnormality in the switching element may employ detection of abnormality by a voltage at the switching element. In this case, known voltage detection means is installed in each of the switching elements 1a, 1b to 6a, 6b, it may thereby be determined whether or not abnormality has occurred on the basis of a voltage value output from the voltage detection means. In the description above, the temperature sensors, the current detection means and voltage detection means may be circuits.

In the above description, the switching elements 1a, 1b to 6a, 6b are IGBTs. However, the switching elements 1a, 1b to 6a, 6b may be another type of switching devices, which are driven by a voltage applied to the gate, such as MOSFET.

In the above description, the motor driving device 2 controls the motor 6 by PWM control. However, the motor driving device 2 may control the motor 6 by another type of control such as PAM control. In the above description, a load driven by a load driving device is the motor 6. However, the load driven by the load driving device may be a heater, a lamp, or the like.

In the foregoing, specific examples of the present invention have been described in detail. However, those are only examples and do not limit the scope of the claims. Technologies recited in the claims include modifications and variations of the specific examples exemplified above. Further, technical elements described in this specification or the drawings provide technical usefulness by themselves or in various combinations. Further, the technologies exemplified in this specification or the drawings can simultaneously achieve a plurality of objects, and achievement of a single object among those provides technical usefulness.

What is claimed is:

1. A switching circuit for switching a state of an energization path between a conduction state and a non-conduction state, the switching circuit comprising:
a first switching element which is arranged in the energization path, turns into the non-conduction state in a case where a gate-on voltage is not applied to a gate, and turns into the conduction state in a case where the gate-on voltage is applied to the gate;
a second switching element which is arranged in parallel with the first switching element in the energization path, turns into the non-conduction state in a case where a gate-on voltage is not applied to a gate, and turns into the conduction state in a case where the gate-on voltage is applied to the gate;
a first abnormality detection portion having a capacity of detecting abnormality in the first switching element;
a second abnormality detection portion having a capacity of detecting abnormality in the second switching element;
a gate driving signal output section which applies the gate-on voltage to each of gate terminals of the first switching element and the second switching element;
a first gate driving line which connects the gate driving signal output section with the gate terminal of the first switching element;
a second gate driving line which connects the gate driving signal output section with the gate terminal of the second switching element;
a first fuse which is provided in the first gate driving line and turns the first gate driving line into the non-conduction state in a case where the first abnormality detection portion detects abnormality in the first switching element; and
a second fuse which is provided in the second gate driving line and turns the second gate driving line into the non-conduction state in a case where the second abnormality detection portion detects abnormality in the second switching element.

2. The switching circuit according to claim 1, further comprising:
a first short-circuit terminal and a second short-circuit terminal to which a reference voltage different from the gate-on voltage is applied;
a first short-circuit line which has one end connected with the first gate driving line in a position between the first fuse and the first switching element and has another end connected with the first short-circuit terminal;
a second short-circuit line which has one end connected with the second gate driving line in a position between the second fuse and the second switching element and has another end connected with the second short-circuit terminal;
a first switch which is provided in the first short-circuit line and turns the first short-circuit line into the conduction state when the first abnormality detection portion detects abnormality in the first switching element; and
a second switch which is provided in the second short-circuit line and turns the second short-circuit line into the conduction state when the second abnormality detection portion detects abnormality in the second switching element,
wherein when the gate driving signal output section applies the gate-on voltage to the gate of the first switching element in the conduction state of the first short-circuit line, current flows from the gate driving signal output section to the first short-circuit terminal, and the first fuse turns into the non-conduction state, and
when the gate driving signal output section applies the gate-on voltage to the gate of the second switching element in the conduction state of the second short-circuit line, current flows from the gate driving signal output section to the second short-circuit terminal, and the second fuse turns into the non-conduction state.

3. The switching circuit according to claim 1,
wherein after abnormality in either one of the first switching element and the second switching element is detected, the gate driving signal output section reduces electric power output from the energization path compared to electric power before detection of the abnormality.

4. The switching circuit according to claim 1,
wherein the first abnormality detection portion having a capacity detecting a temperature of the first switching element,
wherein the second abnormality detection portion having a capacity of detecting a temperature of the second switching element,
the first fuse turns into the non-conduction state when a determination is made that the first switching element is abnormal according to the temperature detected by the first abnormality detection portion, and
the second fuse turns into the non-conduction state when a determination is made that the second switching element is abnormal according to the temperature detected by the second abnormality detection portion.

5. The switching circuit according to claim 1,
wherein the first abnormality detection portion having a capacity of detecting current flowing through the first switching element,
the second abnormality detection portion having a capacity of detecting current flowing through the second switching element,
the first fuse turns into the non-conduction state when a determination is made that the first switching element is abnormal according to the current detected by the first abnormality detection portion, and
the second fuse turns into the non-conduction state when a determination is made that the second switching element is abnormal according to the current detected by the second abnormality detection portion.

6. The switching circuit according to claim 1,
wherein the first abnormality detection portions having a capacity of detecting a voltage applied to the first switching element,
the second abnormality detection portion having a capacity of detecting a voltage applied to the second switching element,
the first fuse turns into the non-conduction state when a determination is made that the first switching element is abnormal according to the voltage detected by the first abnormality detection portion, and
the second fuse turns into the non-conduction state when a determination is made that the second switching element is abnormal according to the voltage detected by the second abnormality detection portions.
